(19) United States
(12) Patent Application Publication
(10) Pub. No.: US 2016/0233016 A1
(43) Pub. Date: Aug. 11, 2016

(54) SYSTEM, APPARATUS, AND METHOD FOR POWER AMPLIFICATION TRANSFORMERS

(71) Applicant: QUALCOMM Incorporated, San Diego, CA (US)

(72) Inventor: Miena Magdi Hakeem ARMANIOUS, La Jolla, CA (US)

(21) Appl. No.: 14/617,922

(22) Filed: Feb. 9, 2015

(51) Int. Cl. H01F 27/28; H05K 1/18; H01F 27/29

(52) U.S. Cl. CPC H01F 27/2804; H01F 27/29; H05K 1/181; H01F 2027/2809

(57) ABSTRACT

A transformer according to some examples may include a first upper secondary winding between a first upper primary winding and a second upper primary winding in the first horizontal plane, a first lower secondary winding between a first lower primary winding and a second lower primary winding in a second horizontal plane below the first horizontal plane, a second upper secondary winding in the first horizontal plane spaced from the second upper primary winding on an opposite side from the first upper secondary winding in a first side of the first horizontal plane, and a second lower secondary winding in the second horizontal plane spaced from the second lower primary winding on an opposite side from the first lower primary winding in a second side of the second horizontal plane.

### FIELD OF DISCLOSURE

This disclosure relates generally power amplification circuits, and more specifically, but not exclusively, power amplification circuits with an off chip transformer.

### BACKGROUND

Transformers play an important role in the matching network of power amplifier (PA) circuitry. In PA implementation on CMOS SOI most transformer designs are done on-chip (BEOL), Such designs utilize a large area of the silicon die that reflects on the overall cost of the chip. It is cost effective to move the transformer matching network on a laminate module to reduce the die size. However, due to the significant increase in the minimum width and spacing metal trace on laminate compare to on-chip and the larger via pad radius, the magnetic coupling coefficient k drops to cause a substantial loss in the output power (Pout) and power-added efficiency (PAE) of the PA.

Typically with an optimized on-chip transformer design, a magnetic coupling factor k>0.7 can be achieved in the HB. This is one of the critical parameters that contributes to Pout and PAE of PA circuits. To achieve a higher k value (>0.7), the line width and spacing between metal traces are reduced. Typical minimum width of line/space (L/S) design rules of CMOS SOI technologies is 2 um/2 um, which offers more flexibility to achieve the desired coupling coefficient value k. When moving to laminate the minimum space/width rules usually start from (25 um/25 um), which degrades the magnetic coupling factor k between the primary and secondary turns. Lower design limits can be fabricated but they are more expensive. Typical metal traces of transformer designed for output match usually utilize 2-3 Cu metal stacks with L/S close to 15 um/15 um. So benefit from moving an on-chip design to a laminate design might not be cost effective. To regain back the loss in the coupling factor k while using a the minimum of 30 um/30 um for the space/width design rules, a transformer with the following characteristics is designed: The 1st turn of the secondary winding is surrounded by 2 by 2 parallel lines from the primary winding to maximize the magnetic flux lines that intercepts the primary and secondary loops. The 2nd turn of the secondary runs as single trace in the inner transformer opening to increase the overall secondary inductance and achieve high impedance transformation ratio. All the metal traces are conformed around via pads to maximize magnetic coupling and improve Q-Factor. It will be shown in the presented work that a laminate design with fairly broadband response that covers low band (LB) at 900 MHz, mid-band (MB) at 1.8 GHz, and high-band (HB) at 2.6 GHz can achieve a much higher Q-factor values while maintaining a k value around 0.7 in less than double the area of an on-chip design, that is much less than the cost/area ratio of Silicon die to laminate module.

Accordingly, there are long-felt industry needs for methods that improve upon conventional methods including the improved methods and apparatus provided hereby.

The inventive features that are characteristic of the teachings, together with further features and advantages, are better understood from the detailed description and the accompanying figures. Each of the figures is provided for the purpose of illustration and description only, and does not limit the present teachings.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In some examples of the disclosure, the system, apparatus, and method includes a transformer having: a first upper primary winding in a first horizontal plane; a second upper primary winding in the first horizontal plane spaced from the first upper primary winding; a first lower primary winding in a second horizontal plane, the second horizontal plane being below the first horizontal plane; a second lower primary winding in the second horizontal plane spaced from the first lower primary winding; a first upper secondary winding in the first horizontal plane between the first upper primary winding and the second upper primary winding and spaced therefrom; a second upper secondary winding in the first horizontal plane spaced from the second upper primary winding on an opposite side from the first upper secondary winding in a first side of the first horizontal plane; a first lower secondary winding in the second horizontal plane between the first lower primary winding and the second lower primary winding and spaced therefrom; and a second lower secondary winding in the second horizontal plane spaced from the second lower primary winding on an opposite side from the first lower primary winding in a second side of the second horizontal plane.

In some examples of the disclosure, the system, apparatus, and method includes a semiconductor package for power amplification circuits having: a semiconductor die having a power amplification circuit; a transformer positioned vertically below the semiconductor die, the transformer having: a first upper primary winding in a first horizontal plane; a second upper primary winding in the first horizontal plane spaced from the first upper primary winding; a first lower primary winding in a second horizontal plane, the second horizontal plane being below the first horizontal plane; a second lower primary winding in the second horizontal plane spaced from the first lower primary winding; a first upper secondary winding in the first horizontal plane between the first upper primary winding and the second upper primary winding and spaced therefrom; a second upper secondary winding in the first horizontal plane spaced from the second upper primary winding on an opposite side from the first upper secondary winding in a first side of the first horizontal plane; a first lower secondary winding in the second horizontal plane between the first lower primary winding and the second lower primary winding and spaced therefrom; and a second lower secondary winding in the second horizontal plane spaced from the second lower primary winding on an opposite side from the first lower primary winding in a second side of the second horizontal plane.

In some examples of the disclosure, the system, apparatus, and method includes a semiconductor package for power amplification circuits having: a semiconductor die; a transformer positioned vertically below the semiconductor die, the transformer having an upper tier in a first horizontal plane, a lower tier in a second horizontal plane below the first horizontal plane, a first secondary winding via extending between the upper tier and the lower tier, and a second secondary winding via extending between the upper tier and the lower tier; a secondary winding having a first secondary turn, a second secondary turn, a secondary input pin, and a secondary output pin; a primary winding having an outer upper primary winding, an inner upper primary winding, an outer lower primary winding, an inner lower primary winding, a primary input pin, and a primary output pin, the outer upper primary winding and the inner upper primary winding being in the upper tier and the outer lower primary winding and the inner lower primary winding being in the lower tier; wherein the first secondary turn being positioned between the outer upper primary winding and the inner upper primary winding; wherein the primary input pin, the primary output pin, the secondary input pin, and the secondary output pin are located on a first side of the transformer vertically below the semiconductor die and connect the transformer to the semiconductor die; and wherein the first secondary winding via and the second secondary winding via are located on a second side of the transformer, the second side of the transformer being opposite the first side.

In some examples of the disclosure, the system, apparatus, and method includes a semiconductor package having: a semiconductor die; and a transformer positioned below the semiconductor die and electrically connected to the semiconductor die, wherein the transformer further comprises: a first secondary winding turn in an upper horizontal plane, the first secondary winding turn positioned between a first primary winding and a second primary winding, the first secondary winding turn having a secondary input pin, a secondary output pin, a first via pad, and a second via pad; the first primary winding connected to a primary input pin and a primary output pin; and the second primary winding connected to the primary input pin, the primary output pin, a third via pad, and a fourth via pad.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary processor in accordance with some examples of the disclosure.

FIG. 2 illustrates exemplary user equipment (UE) in accordance with some examples of the disclosure.

FIG. 3 illustrates an exemplary transformer in accordance with some examples of the disclosure.

FIG. 4 illustrates a top and side view of an exemplary transformer in accordance with some examples of the disclosure.

FIG. 5 illustrates an exemplary PA package in accordance with some examples of the disclosure.

FIG. 6 illustrates an exemplary transformer in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein advantageously address the long-felt industry needs, as well as other previously unidentified needs, and mitigate shortcomings of the conventional methods, apparatus, and systems.

Various aspects are disclosed in the following description and related drawings to show specific examples relating to the disclosure. Alternate examples will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and examples disclosed herein.

The word “exemplary” is used herein to mean “serving as an example, instance, or illustration.” Any details described herein as “exemplary” is not necessarily to be construed as preferred or advantageous over other examples. Likewise, the term “examples” does not require that all examples include the discussed feature, advantage or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples only and is not intended to be limiting of examples of the disclosure. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element. Coupling and/or connection between the elements can be physical, logical, or a combination thereof. As employed herein, elements can be “connected” or “coupled” together, for example, by using one or more wires, cables, and/or printed electrical connections, as well as by using electromagnetic energy. The electromagnetic energy can have wavelengths in the radio frequency region, the microwave region and/or the optical (both visible and invisible) region. These are several non-limiting and non-exhaustive examples.

It should be understood that the term “signal” can include any signal such as a data signal, audio signal, video signal, multimedia signal, analog signal, and/or digital signal. Information and signals can be represented using any of a variety of different technologies and techniques. For example, data, an instruction, a process step, a command, information, a signal, a bit, and/or a symbol described in this description can be represented by a voltage, a current, an electromagnetic wave, a magnetic field and/or particle, an optical field and/or particle, and any combination thereof.

Any reference herein to an element using a designation such as “first,” “second,” and so forth does not limit the quantity and/or order of those elements. Rather, these designations are used as a convenient method of distinguishing between two or more elements and/or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” used in the description or the claims can be interpreted as “A or B or C or any combination of these elements.”

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the examples described herein, the corresponding form of any such examples may be described herein as, for example, “logic configured to” perform the described action.

In this description, certain terminology is used to describe certain features. The term “mobile device” can describe, and is not limited to, a mobile phone, a mobile communication device, a pager, a personal digital assistant, a personal information manager, a mobile hand-held computer, a laptop computer, a wireless device, a wireless modem, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

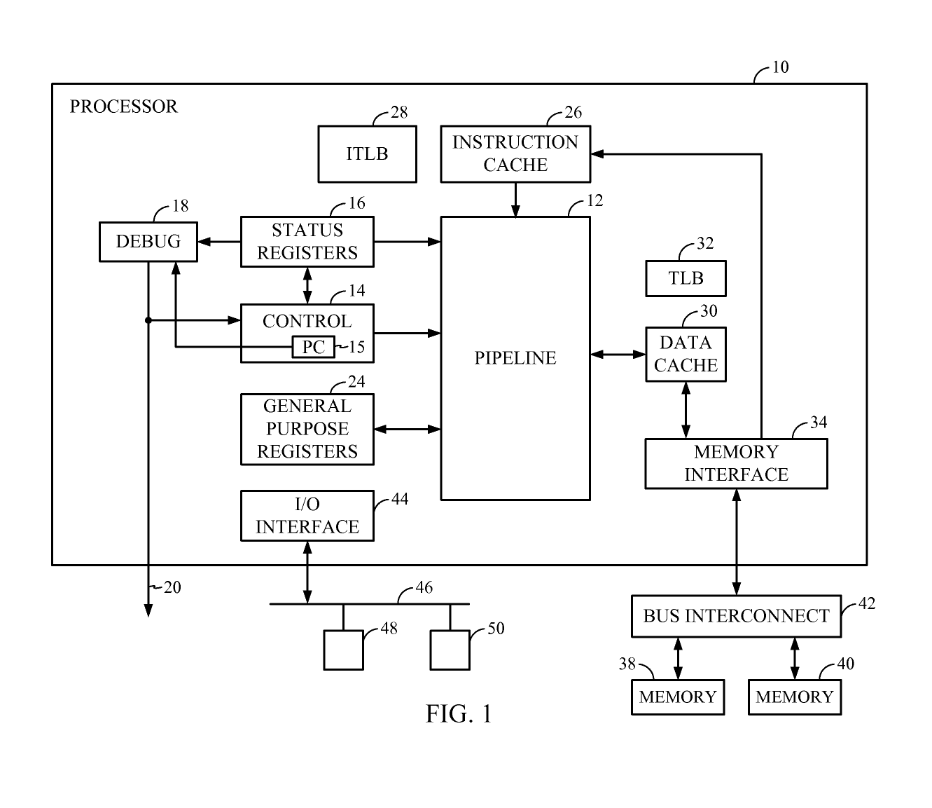

FIG. 1 depicts a functional block diagram of an exemplary processor 10, such as an ASIC 208 (see below). Processor 10 executes instructions in an instruction execution pipeline 12 according to control logic 14. Control logic 14 maintains a Program Counter (PC) 15, and sets and clears bits in one or more status registers 16 to indicate, e.g., the current instruction set operating mode, information regarding the results of arithmetic operations and logical comparisons (zero, carry, equal, not equal), and the like. In some examples, pipeline 12 may be a superscalar design, with multiple, parallel pipelines. Pipeline 12 may also be referred to as an execution unit. A General Purpose Register (GPR) file 20 provides a list of general purpose registers 24 accessible by pipeline 12, and comprising the top of the memory hierarchy.

Processor 10, which executes instructions from at least two instruction sets in different instruction set operating modes, additionally includes a debug circuit 18, operative to compare, upon the execution of each instruction, at least a predetermined target instruction set operating mode to the current instruction set operating mode, and to provide an indication of a match between the two.

Pipeline 12 fetches instructions from an instruction cache (I-cache) 26, with memory address translation and permissions managed by an Instruction-side Translation Lookaside Buffer (ITLB) 28. Data is accessed from a data cache (D-cache) 30, with memory address translation and permissions managed by a main Translation Lookaside Buffer (TLB) 32. In various examples, ITLB 28 may comprise a copy of part of TLB 32. Alternatively, ITLB 28 and TLB 32 may be integrated. Similarly, in various examples of processor 10, I-cache 26 and D-cache 30 may be integrated, or unified. Further, I-cache 26 and D-cache 30 may be L1 caches. Misses in I-cache 26 and/or D-cache 30 cause an access to main (off-chip) memory 38, 40 by a memory interface 34. Memory interface 34 may be a master input to a bus interconnect 42 implementing a shared bus to one or more memory devices 38, 40 that may incorporate the improved data decompression in accordance with some examples of the disclosure. Additional master devices (not shown) may additionally connect to bus interconnect 42.

Processor 10 may include input/output (I/O) interface 44, which may be a master device on a peripheral bus, across which I/O interface 44 may access various peripheral devices 48, 50 via bus 46. Those of skill in the art will recognize that numerous variations of processor 10 are possible. For example, processor 10 may include a second-level (L2) cache for either or both I and D caches 26, 30. In addition, one or more of the functional blocks depicted in processor 10 may be omitted from a particular example. Other functional blocks that may reside in processor 10, such as a JTAG controller, instruction pre-decoder, branch target address cache, and the like are not germane to a description of the present disclosure, and are omitted for clarity.

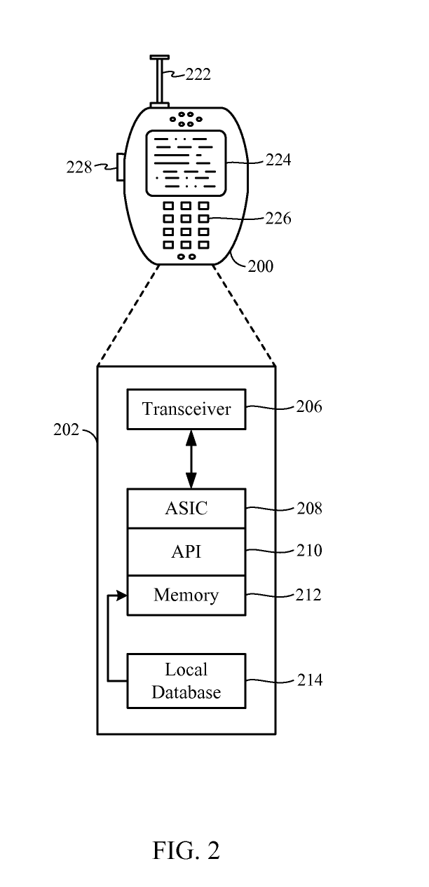

Referring to FIG. 2, a system 100 that includes a UE 200, (here a wireless device), such as a cellular telephone, which has a platform 202 that can receive and execute software applications, data and/or commands transmitted from a radio access network (RAN) that may ultimately come from a core network, the Internet and/or other remote servers and networks. Platform 202 can include transceiver 206 operably coupled to an application specific integrated circuit (“ASIC” 208), or other processor, microprocessor, logic circuit, or other data processing device. ASIC 208 or other processor executes the application programming interface (“API”) 210 layer that interfaces with any resident programs in memory 212 of the wireless device. Memory 212 can be comprised of read-only or random-access memory (RAM and ROM), EEPROM, flash cards, or any memory common to computer platforms. Platform 202 also can include local database 214 that can hold applications not actively used in memory 212. Local database 214 is typically a flash memory cell, but can be any secondary storage device as known in the art, such as magnetic media, EEPROM, optical media, tape, soft or hard disk, or the like. Internal platform 202 components can also be operably coupled to external devices such as antenna 222, display 224, push-to-talk button 228 and keypad 226 among other components, as is known in the art.

Accordingly, an example of the disclosure can include a UE including the ability to perform the functions described herein. As will be appreciated by those skilled in the art, the various logic elements can be embodied in discrete elements, software modules executed on a processor or any combination of software and hardware to achieve the functionality disclosed herein. For example, ASIC 208, memory 212, API 210 and local database 214 may all be used cooperatively to load, store and execute the various functions disclosed herein and thus the logic to perform these functions may be distributed over various elements. Alternatively, the functionality could be incorporated into one discrete component. Therefore, the features of UE 200 in FIG. 2 are to be considered merely illustrative and the disclosure is not limited to the illustrated features or arrangement.

The wireless communication between UE 200 and the RAN can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE) or other protocols that may be used in a wireless communications network or a data communications network.

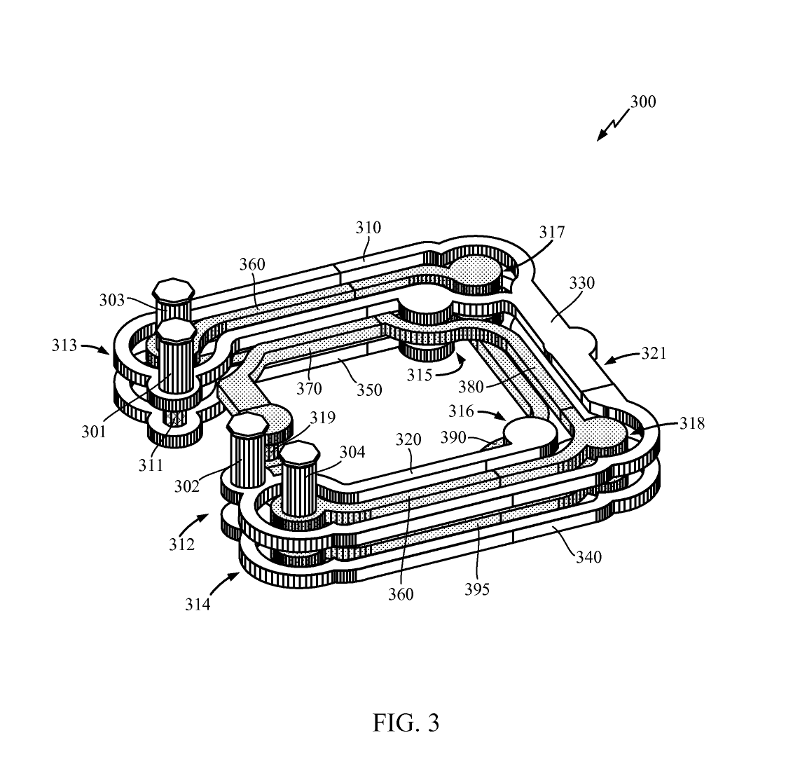

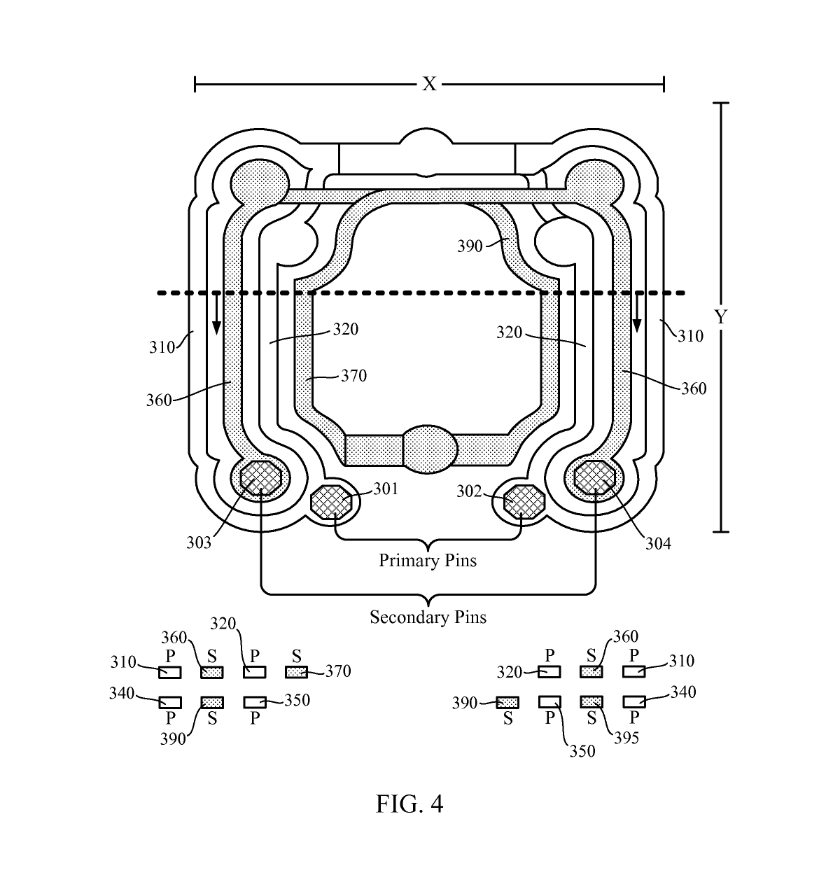

FIGS. 3 and 4 illustrates an exemplary transformer in accordance with some examples of the disclosure. As shown in FIGS. 3 and 4, a transformer 300 may include a first upper primary winding 310, a second upper primary winding 320, and a primary transition portion 330, a first lower primary winding 340, a second lower primary winding 350, a first upper secondary winding 360, a second upper secondary winding 370, a secondary transition portion 380, a first lower secondary winding 390, a second lower secondary winding 395. The first upper primary winding 310, the second upper primary winding 320, the first upper secondary winding 360, and the second upper secondary winding 370 may be co-located in the same first horizontal plane. The first lower primary winding 340, the second lower primary winding 350, the first lower secondary winding 390, and the second lower secondary winding 395 may be co-located in the same second horizontal plane vertically below the first horizontal plane. The primary transition portion 330 and the secondary transition portion 380 may include portions in both the first horizontal plane and the second horizontal plane to allow transition of the primary windings and secondary windings from a first side of the first and second horizontal planes to a second side of the first and second horizontal planes as shown in FIGS. 3 and 4.

In the first horizontal plane as shown in FIGS. 3 and 4, the first upper secondary winding 360 is located between the first upper primary winding 310 and the second upper primary winding 320 on both the first side and the second side of the first horizontal plane. The second upper secondary winding 370 is located on the first side of the first horizontal plane towards the interior of the transformer 300 on an opposite side of the second upper primary winding 320 from the first upper secondary winding 360.

In the second horizontal plane as shown in FIGS. 3 and 4, the first lower secondary winding 395 is located between the first lower primary winding 340 and the second lower primary winding 350 on both the first side and the second side of the second horizontal plane. The second lower secondary winding 390 is located on the second side of the second horizontal plane towards the interior of the transformer 300 on an opposite side of the second lower primary winding 350 from the first lower secondary winding 395.

The transformer 300 may include a first primary pin 301, a second primary pin 302, a first secondary pin 303, and a second secondary pin 304 all located on a same side of transformer 300 and extending vertically upward for input/output connections to a PA circuit (not shown). The first primary pin 301 is coupled to the first upper primary winding 310 and the second upper primary winding 320 on the first side of the first horizontal plane. The second primary pin 302 is coupled to the first upper primary winding 310 and the second upper primary winding 320 on the second side of the first horizontal plane. The first secondary pin 303 is coupled to the first upper secondary winding 360 on the first side of the first horizontal plane. The second secondary pin 304 is coupled to the first upper secondary winding 360 on the second side of the first horizontal plane.

The transformer 300 may include a first via 311 below the first primary pin 301 extending vertically between the first horizontal plane and the second horizontal plane to couple the first upper primary winding 310 and the second upper primary winding 320 to the first lower primary winding 340 and the second lower primary winding 350, a second via 312 below the second primary pin 302 extending vertically between the first horizontal plane and the second horizontal plane to couple the first upper primary winding 310 and the second upper primary winding 320 to the first lower primary winding 340 and the second lower primary winding 350, a third via 313 below the first secondary pin 303 extending vertically between the first horizontal plane and the second horizontal plane to couple the first upper secondary winding 360 to the first lower secondary winding 390, a fourth via 314 below the second secondary pin 304 extending vertically between the first horizontal plane and the second horizontal plane to couple the second upper secondary winding 360 to the second lower secondary winding 395, a fifth via 315 extending vertically between the first horizontal plane and the second horizontal plane to couple the second upper primary winding 320 to the second lower primary winding 350, a sixth via 316 extending vertically between the first horizontal plane and the second horizontal plane to couple the second upper primary winding 320 and the second lower primary winding 395, a seventh via 317 extending vertically between the first horizontal plane and the second horizontal plane to couple the first upper secondary winding 360 to the first lower secondary winding 390, an eighth via 318 extending vertically between the first horizontal plane and the second horizontal plane to couple the second upper secondary winding 360 to the second lower secondary winding 395, a ninth via 319 located between the first and second sides of the first and second horizontal planes extending vertically between the first horizontal plane and the second horizontal plane to couple the second upper secondary winding 370 to the second lower secondary winding 395, and a tenth via 321 located between the first and second sides of the first and second horizontal planes extending vertically between the first horizontal plane and the second horizontal plane to couple an upper portion of the primary transition portion 330 to a lower portion of the primary transition portion 330.

As shown in FIG. 4, the first upper primary winding 310, second upper primary winding 320, first lower primary winding 340, and second lower primary winding 350 may be configured to partially encircle or enclose the third via 313 in both the first and second horizontal plane, the seventh via in the first horizontal plane, the eight via 318 in the second horizontal plane, the fourth via 314 in the first and second horizontal plane. By encircling or enclosing the vias, the inductance between the primary and secondary windings may be increased.

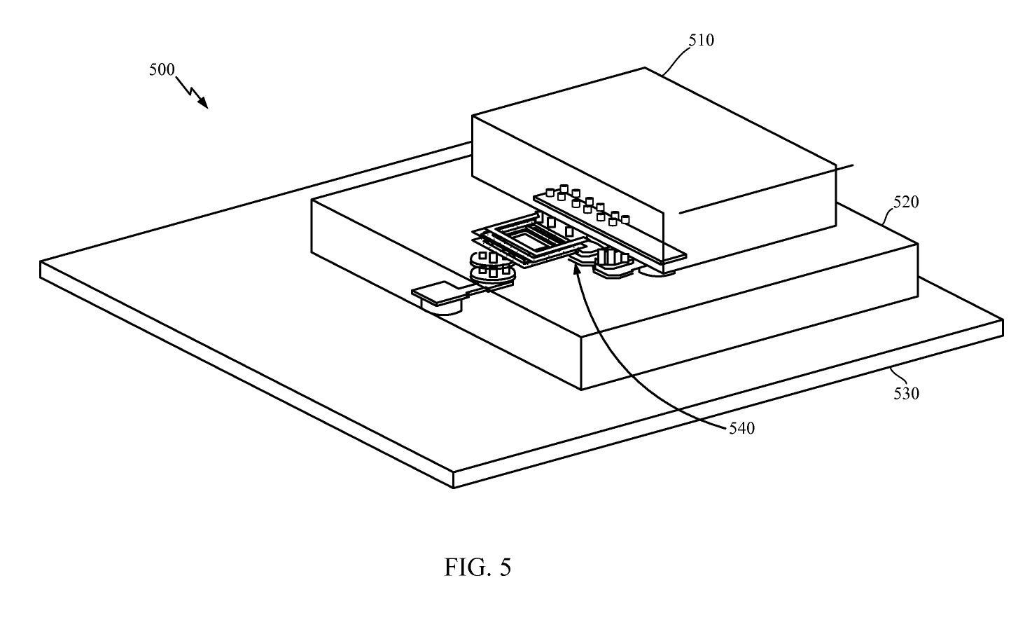

FIG. 5 illustrates an exemplary PA package in accordance with some examples of the disclosure. As shown in FIG. 5, a semiconductor package 500 may include a silicon based semiconductor die 510 having a PA circuit (not shown) integrated therein, a laminate module 520 having a planar transformer 540 therein and located below the semiconductor die 510, and a printed circuit board located below the laminate module 520. The semiconductor die 510 has a smaller perimeter than the laminate module 520 and the laminate module 520 has a smaller perimeter than the printed circuit board. It should be understood that these components may have the same, smaller, or larger diameters than the other components. However, when the laminate module 520 has a larger perimeter than the semiconductor die 510, the transformer 540 can be offset from the semiconductor die such that a portion of the transformer 540 extends beyond the perimeter of the semiconductor die 510 while the primary pins and secondary pins are located directly under the semiconductor die 510. This will allow an increase in the heat dissipation from the transformer 540 as well as short runs for the pins to the PA circuit in the die.

In one example, the x and y dimensions (shown in FIG. 4) may be 810 μm and 840 μm respectively with the windings having a line width of 30 μm and spacing width of 30 μm and a thickness of 18 μm, via pad diameters (the top and bottom landing pads for the vias) may be 100 μm, via diameters may be 40 μm and a height may be 35 μm, the primary and secondary pins may have a height of 76 μm and a bump diameter (for coupling to the PA circuit) may be 60 μm, and a laminate Eᵣ of 4.6. In such an example, any loss (versus embedding the transformer in the silicon die) in the coupling factor k while using the minimum of 30 um/30 um for the space/width design can be regained. In this example, the 1^{st} turn of the secondary winding is surrounded by 2 by 2 parallel lines from the primary winding to maximize the magnetic flux lines that intercepts the primary and secondary loops, the 2^{nd} turn of the secondary runs as single trace in the inner transformer opening to increase the overall secondary inductance and achieve high impedance transformation ratio, the metal traces are conformed around the via pads to maximize magnetic coupling and improve Q-Factor, and the transformer windings utilizing only two metal layers on laminate. The laminate design exhibits a fairly broadband response that covers low band (LB), middle band (MB), and high band (HB) that can achieve a much higher Q at HB (for example 2.6 GHz) values while maintaining a k value around 0.7 in less than double the area of an on-chip transformer design.

In another example, the x and y dimensions (shown in FIG. 4) may be 1010 μm and 1100 μm respectively with the windings having a line width of 50 μm and spacing width of 50 μm and a thickness of 18 μm, via pad diameters (the top and bottom landing pads for the vias) may be 160 μm, via diameters may be 70 μm and a height may be 35 μm, the primary and secondary pins may have a height of 76 μm and a bump diameter (for coupling to the PA circuit) may be 100 μm, and a laminate Eᵣ of 4.6. In such an example, any loss (versus embedding the transformer in the silicon die) in the coupling factor k while using the 50 um/50 um for the space/width design can be regained.

The following tables (table 1—LB of 900 MHz, table 2—HB of 2.6 GHz) illustrate the simulated transformer characteristics for the two examples above:

TABLE 1

| S/W | Lₚᵣᵢ | Qₚᵣᵢ | L_{sec} | Q_{sec} | k |
|---|---|---|---|---|---|
| 30/30 | 0.63 nH | 23 | 2.4 nH | 28 | 0.69 |
| 50/50 | 0.64 nH | 25 | 2.0 nH | 29 | 0.6 |

TABLE 2

| S/W | Lₚᵣᵢ | Qₚᵣᵢ | L_{sec} | Q_{sec} | k |
|---|---|---|---|---|---|
| 30/30 | 0.63 nH | 41 | 2.45 nH | 45 | 0.7 |
| 50/50 | 0.64 nH | 40 | 2.0 nH | 44 | 0.63 |

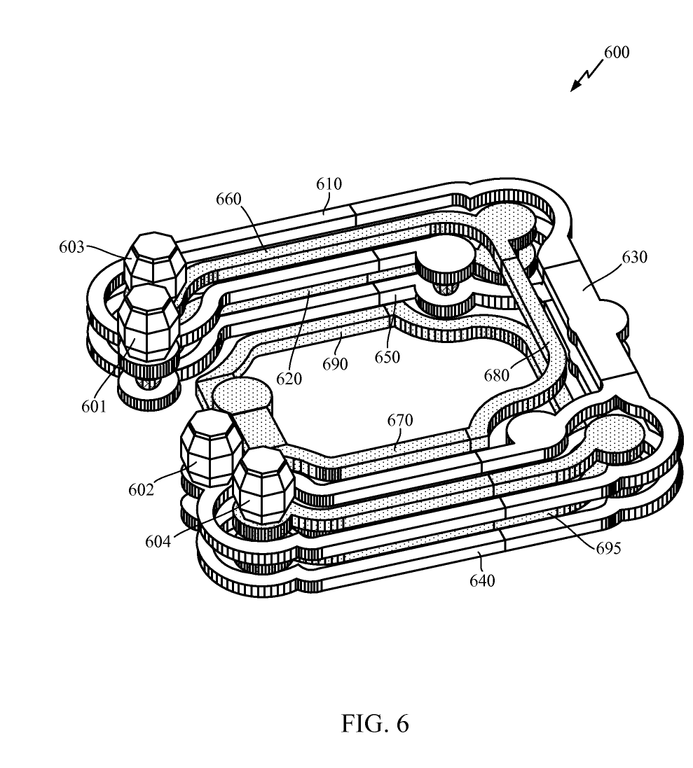

FIG. 6 illustrates an exemplary transformer in accordance with some examples of the disclosure. As shown in FIG. 6, a transformer 600 may include a first upper primary winding 610, a second upper primary winding 620, and a primary transition portion 630, a first lower primary winding 640, a second lower primary winding 650, a first upper secondary winding 660, a second upper secondary winding 670, a secondary transition portion 680, a first lower secondary winding 690, a second lower secondary winding 695. The first upper primary winding 610, the second upper primary winding 620, the first upper secondary winding 660, and the second upper secondary winding 670 may be co-located in the same first horizontal plane. The first lower primary winding 640, the second lower primary winding 650, the first lower secondary winding 690, and the second lower secondary winding 695 may be co-located in the same second horizontal plane vertically below the first horizontal plane. The primary transition portion 630 and the secondary transition portion 680 may include portions in both the first horizontal plane and the second horizontal plane to allow transition of the primary windings and secondary windings from a first side of the first and second horizontal planes to a second side of the first and second horizontal planes as shown in FIG. 6.

In the first horizontal plane as shown in FIG. 6, the first upper secondary winding 660 is located between the first upper primary winding 610 and the second upper primary winding 620 on both the first side and the second side of the first horizontal plane. The second upper secondary winding 670 is located on the second side of the first horizontal plane towards the interior of the transformer 600 on an opposite side of the second upper primary winding 620 from the first upper secondary winding 660.

In the second horizontal plane as shown in FIG. 6, the first lower secondary winding 695 is located between the first lower primary winding 640 and the second lower primary winding 650 on both the first side and the second side of the second horizontal plane. The second lower secondary winding 690 is located on the first side of the second horizontal plane towards the interior of the transformer 600 on an opposite side of the second lower primary winding 650 from the first lower secondary winding 695.

The transformer 600 may include a first primary pin 601, a second primary pin 602, a first secondary pin 603, and a second secondary pin 604 all located on a same side of transformer 600 and extending vertically upward for input/output connections to a PA circuit (not shown). The pins 601-604 are shown as solder bumps, but it should be understood that they may be solder balls or other types of electrical connections to connect the respective transformer windings to the semiconductor die (not shown). The first primary pin 601 is connected to the first upper primary winding 610 and the second upper primary winding 620 on the first side of the first horizontal plane. The second primary pin 602 is connected to the first upper primary winding 610 and the second upper primary winding 620 on the second side of the first horizontal plane. The first secondary pin 603 is connected to the first upper secondary winding 660 on the first side of the first horizontal plane. The second secondary pin 604 is connected to the first upper secondary winding 660 on the second side of the first horizontal plane.

Examples of the methods, apparatus, and systems described herein can be used in a number of applications, such as power amplifiers that are implemented on a CMOS die mounted on a module. Further applications should be readily apparent to those of ordinary skill in the art.

Nothing stated or illustrated depicted in this application is intended to dedicate any component, step, feature, benefit, advantage, or equivalent to the public, regardless of whether the component, step, feature, benefit, advantage, or the equivalent is recited in the claims.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method step or as a feature of a method step. Analogously thereto, aspects described in connection with or as a method step also constitute a description of a corresponding block or detail or feature of a corresponding device. Some or all of the method steps can be performed by a hardware apparatus (or using a hardware apparatus), such as, for example, a microprocessor, a programmable computer or an electronic circuit. In some examples, some or a plurality of the most important method steps can be performed by such an apparatus.

The examples described above merely constitute an illustration of the principles of the present disclosure. It goes without saying that modifications and variations of the arrangements and details described herein will become apparent to other persons skilled in the art. Therefore, it is intended that the disclosure be restricted only by the scope of protection of the appended patent claims, rather than by the specific details presented on the basis of the description and the explanation of the examples herein.

In the detailed description above it can be seen that different features are grouped together in examples. This manner of disclosure should not be understood as an intention that the claimed examples require more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods disclosed in the description or in the claims can be implemented by a device comprising means for performing the respective steps or actions of this method.

Furthermore, in some examples, an individual step/action can be subdivided into a plurality of sub-steps or contain a plurality of sub-steps. Such sub-steps can be contained in the disclosure of the individual step and be part of the disclosure of the individual step.

While the foregoing disclosure shows illustrative examples of the disclosure, it should be noted that various changes and modifications could be made herein without departing from the scope of the disclosure as defined by the appended claims. The functions, steps and/or actions of the method claims in accordance with the examples of the disclosure described herein need not be performed in any particular order. Furthermore, although elements of the disclosure may be described or claimed in the singular, the plural is contemplated unless limitation to the singular is explicitly stated.

What is claimed is:

1. A transformer, comprising:
a first upper primary winding in a first horizontal plane;
a second upper primary winding in the first horizontal plane spaced from the first upper primary winding;
a first lower primary winding in a second horizontal plane, the second horizontal plane being below the first horizontal plane;
a second lower primary winding in the second horizontal plane spaced from the first lower primary winding;
a first upper secondary winding in the first horizontal plane between the first upper primary winding and the second upper primary winding and spaced therefrom;
a second upper secondary winding in the first horizontal plane spaced from the second upper primary winding on an opposite side from the first upper secondary winding in a first side of the first horizontal plane;
a first lower secondary winding in the second horizontal plane between the first lower primary winding and the second lower primary winding and spaced therefrom; and
a second lower secondary winding in the second horizontal plane spaced from the second lower primary winding on an opposite side from the first lower primary winding in a second side of the second horizontal plane.

2. The transformer of claim 1, further comprising:
a first primary pin;
a second primary pin;
a primary center tap pin;
a first secondary pin;
a second secondary pin; and
a secondary center tap pin;
wherein the first primary pin, the second primary pin, the first secondary pin, and the second secondary pin are solder bumps located on a same side to be connected to a die.

3. The transformer of claim 2, wherein the first primary pin is connected to the first upper primary winding and the second upper primary winding on the first side of the first horizontal plane, the second primary pin is connected to the first upper primary winding and the second upper primary winding on the second side of the first horizontal plane, the first secondary pin is connected to the first upper secondary winding on the first side of the first horizontal plane, and the second secondary pin is connected to the first upper secondary winding on the second side of the first horizontal plane.

4. The transformer of claim 3, further comprising:
a first via located below the first primary pin extending vertically between the first horizontal plane and the second horizontal plane to connect the first upper primary winding and the second upper primary winding to the first lower primary winding and the second lower primary winding;
a second via located below the second primary pin extending vertically between the first horizontal plane and the second horizontal plane to connect the first upper primary winding and the second upper primary winding to the first lower primary winding and the second lower primary winding;
a third via located below the first secondary pin extending vertically between the first horizontal plane and the second horizontal plane to connect the first upper secondary winding to the first lower secondary winding; and
a fourth via located below the second secondary pin extending vertically between the first horizontal plane and the second horizontal plane to connect the second upper secondary winding to the second lower secondary winding.

5. The transformer of claim 4, further comprising:
a fifth via extending vertically between the first horizontal plane and the second horizontal plane to electrically connect the second upper primary winding to the second lower primary winding;
a sixth via extending vertically between the first horizontal plane and the second horizontal plane to electrically connect the second upper primary winding and the second lower primary winding;
a seventh via extending vertically between the first horizontal plane and the second horizontal plane to electrically connect the first upper secondary winding to the first lower secondary winding; and
an eighth via extending vertically between the first horizontal plane and the second horizontal plane to electrically connect the second upper secondary winding to the second lower secondary winding.

6. The transformer of claim 5, further comprising:
a ninth via located between the first side and second side of the first horizontal plane and second horizontal plane extending vertically between the first horizontal plane and the second horizontal plane to electrically connect the second upper secondary winding to the second lower secondary winding; and
a tenth via located between the first side and second side of the first horizontal plane and second horizontal plane extending vertically between the first horizontal plane and the second horizontal plane to electrically connect an upper portion of a primary winding to a lower portion of the primary winding.

7. The transformer of claim 6, wherein the first upper primary winding and the second upper primary winding are configured to partially encircle a third via pad in the first horizontal plane.

8. The transformer of claim 7, wherein the first lower primary winding and the second lower primary winding are configured to partially encircle a third via pad in the second horizontal plane.

9. The transformer of claim 8, wherein the first upper primary winding and the second upper primary winding are configured to partially encircle a seventh via pad in the first horizontal plane.

10. The transformer of claim 9, wherein the first lower primary winding and the second lower primary winding are configured to partially encircle an eighth via pad in the second horizontal plane.

11. The transformer of claim 10, wherein the first upper primary winding and the second upper primary winding are configured to partially encircle a fourth via pad in the first horizontal plane.

12. The transformer of claim 11, wherein the first lower primary winding and the second lower primary winding are configured to partially encircle a fourth via pad in the second horizontal plane.

13. The transformer of claim 12, wherein the first upper primary winding, the second upper primary winding, the first lower primary winding, the second lower primary winding, the first upper secondary winding, the second upper secondary winding, the first lower secondary winding, and the second lower secondary winding have a horizontal width of 30 μm and a spacing of 30 μm.

14. The transformer of claim 12, wherein the first upper primary winding, the second upper primary winding, the first lower primary winding, the second lower primary winding, the first upper secondary winding, the second upper secondary winding, the first lower secondary winding, and the second lower secondary winding are integrated into a laminate module.

15. The transformer of claim 12, wherein in the transformer is integrated into one of a mobile phone, a mobile communication device, a pager, a personal digital assistant, a personal information manager, a mobile hand-held computer, a laptop computer, a wireless device, or a wireless modem.

16. A semiconductor package for power amplification circuits, comprising:
a semiconductor die mounted on a laminated module having a power amplification circuit;
a transformer positioned in the laminated module vertically below the semiconductor die, the transformer having:
a first upper primary winding in a first horizontal plane;
a second upper primary winding in the first horizontal plane spaced from the first upper primary winding;
a first lower primary winding in a second horizontal plane, the second horizontal plane being below the first horizontal plane;
a second lower primary winding in the second horizontal plane spaced from the first lower primary winding;
a first upper secondary winding in the first horizontal plane between the first upper primary winding and the second upper primary winding and spaced therefrom;
a second upper secondary winding in the first horizontal plane spaced from the second upper primary winding on an opposite side from the first upper secondary winding in a first side of the first horizontal plane;
a first lower secondary winding in the second horizontal plane between the first lower primary winding and the second lower primary winding and spaced therefrom; and
a second lower secondary winding in the second horizontal plane spaced from the second lower primary winding on an opposite side from the first lower primary winding in a second side of the second horizontal plane.

17. The semiconductor package of claim 16, wherein the transformer further comprises:
a first primary pin;
a second primary pin;
a primary center tap pin;
a first secondary pin; and
a second secondary pin;
a secondary center tap pin;
wherein the first primary pin, the second primary pin, the first secondary pin;
and the second secondary pin are solder bumps located on a same side and extend upward from the first horizontal plane to electrically connect with the semiconductor die.

18. The semiconductor package of claim 17, wherein the first primary pin is connected to the first upper primary winding and the second upper primary winding on the first side of the first horizontal plane, the second primary pin is connected to the first upper primary winding and the second upper primary winding on the second side of the first horizontal plane, the first secondary pin is connected to the first upper secondary winding on the first side of the first horizontal plane, and the second secondary pin is connected to the first upper secondary winding on the second side of the first horizontal plane.

19. The semiconductor package of claim 18, wherein the transformer further comprises:
a first via located below the first primary pin extending vertically between the first horizontal plane and the second horizontal plane to connect the first upper primary winding and the second upper primary winding to the first lower primary winding and the second lower primary winding;
a second via located below the second primary pin extending vertically between the first horizontal plane and the second horizontal plane to connect the first upper primary winding and the second upper primary winding to the first lower primary winding and the second lower primary winding;
a third via located below the first secondary pin extending vertically between the first horizontal plane and the second horizontal plane to connect the first upper secondary winding to the first lower secondary winding; and
a fourth via located below the second secondary pin extending vertically between the first horizontal plane and the second horizontal plane to connect the second upper secondary winding to the second lower secondary winding.

20. The semiconductor package of claim 19, wherein the transformer further comprises:
a fifth via extending vertically between the first horizontal plane and the second horizontal plane to connect the second upper primary winding to the second lower primary winding;
a sixth via extending vertically between the first horizontal plane and the second horizontal plane to connect the second upper primary winding and the second lower primary winding;
a seventh via extending vertically between the first horizontal plane and the second horizontal plane to connect the first upper secondary winding to the first lower secondary winding; and
an eighth via extending vertically between the first horizontal plane and the second horizontal plane to connect the second upper secondary winding to the second lower secondary winding.

21. The semiconductor package of claim 16, wherein the transformer further comprises:
a ninth via located between the first side and second side of the first horizontal plane and second horizontal plane extending vertically between the first horizontal plane and the second horizontal plane to connect the second upper secondary winding to the second lower secondary winding; and
a tenth via located between the first side and second side of the first horizontal plane and second horizontal plane extending vertically between the first horizontal plane and the second horizontal plane to connect a supply voltage to the transformer for regulating the supply voltage for the power amplification circuit.

22. The semiconductor package of claim 21, wherein the first upper primary winding and the second upper primary winding are configured to partially encircle a third via pad in the first horizontal plane.

23. The semiconductor package of claim 16, wherein the first lower primary winding and the second lower primary winding are configured to partially encircle a third via pad in the second horizontal plane.

24. A semiconductor package for power amplification circuits, comprising:
a semiconductor die mounted on a laminated module;
a transformer in the laminated module positioned vertically below the semiconductor die, the transformer having an upper tier in a first horizontal plane, a lower tier in a second horizontal plane below the first horizontal plane, a first secondary winding via extending between the upper tier and the lower tier, and a second secondary winding via extending between the upper tier and the lower tier;
a secondary winding having a first secondary turn, a second secondary turn, a secondary input pin, and a secondary output pin;
a primary winding having an outer upper primary winding, an inner upper primary winding, an outer lower primary winding, an inner lower primary winding, a primary input pin, and a primary output pin, the outer upper primary winding and the inner upper primary winding being in the upper tier and the outer lower primary winding and the inner lower primary winding being in the lower tier;
wherein the first secondary turn being positioned between the outer upper primary winding and the inner upper primary winding;
wherein the primary input pin, the primary output pin, the secondary input pin, and the secondary output pin are located on a first side of the transformer vertically below the semiconductor die and connect the transformer to the semiconductor die; and
wherein the first secondary winding via and the second secondary winding via are located on a second side of the transformer, the second side of the transformer being opposite the first side.

25. The semiconductor package of claim 24, wherein the transformer includes a first portion located vertically below the semiconductor die and a second portion extending horizontally passed an outer edge of the semiconductor die, the second portion being larger in area than the first portion.

26. A package, comprising:
a laminated module;
a semiconductor die; and
a transformer positioned below the semiconductor die in the laminated module and electrically connected to the semiconductor die, wherein the transformer further comprises:
a first secondary winding turn in an upper horizontal plane, the first secondary winding turn positioned between a first primary winding and a second primary winding, the first secondary winding turn having a secondary input pin, a secondary output pin, a first via pad, and a second via pad;
the first primary winding connected to a primary input pin and a primary output pin; and
the second primary winding connected to the primary input pin, the primary output pin, a third via pad, and a fourth via pad.

27. The semiconductor package of claim 26, wherein the secondary input pin is adjacent the primary input pin and the secondary output pin is adjacent the primary output pin on a same side of the transformer.

28. The semiconductor package of claim 27, wherein the transformer is in a first substrate layer composed of material different from the semiconductor die.

29. The semiconductor package of claim 28, wherein the transformer has a first layer positioned above a second layer.

30. The semiconductor package of claim 29, wherein the transformer has a coupling factor greater than 0.7.
